(19) United States
(12) Patent Application Publication
(10) Pub. No.: US 2020/0362452 A1
(43) Pub. Date: Nov. 19, 2020

(54) FILM FORMING APPARATUS, METHOD FOR MANUFACTURING FILM-FORMED PRODUCT, AND METHOD FOR MANUFACTURING ELECTRONIC COMPONENT

(71) Applicant: Shibaura Mechatronics Corporation, Yokohama-shi (JP)

(72) Inventor: Akihiko Ito, Yokohama-shi (JP)

(21) Appl. No.: 16/987,984

(22) Filed: Aug. 7, 2020

Related U.S. Application Data
(62) Division of application No. 15/636,414, filed on Jun. 28, 2017.

(30) Foreign Application Priority Data
Jun. 28, 2016 (JP) 2016-128119

(51) Int. Cl. C23C 14/34; C23C 14/35; C23C 14/20; C23C 14/50; H01J 37/32; H01J 37/34; H01L 23/552

(52) U.S. Cl. CPC C23C 14/3464; C23C 14/352; C23C 14/205; C23C 14/505; H01L 2224/16227; H01J 37/3429; H01L 23/552; H01L 2924/15311; H01L 2924/3025; H01J 37/32715

(57) ABSTRACT

A film forming apparatus includes a chamber that is a container in which a sputter gas is introduced, a carrying unit provided inside the chamber, and circulating and carrying a work-piece on a trajectory of a circular circumference, and a film formation processing unit including a sputter source depositing, on the work-piece circulated and carried by the carrying unit, a film formation material by sputtering to form a film, and a dividing member dividing a film forming position where the film is formed on the work-piece by the sputter source. The dividing member is installed so as to divide the film forming position in a way that, in the trajectory of the circular circumference, a trajectory of passing through a region other than the film forming position performing the film formation is longer than a trajectory of passing through the film forming position performing the film formation.

### FIELD OF THE INVENTION

This application is based upon and claims the benefit of priority from Japan Patent Application No. 2016-128119, filed on Jun. 28, 2016, the entire contents of which are incorporated herein by reference.

The present disclosure relates to a film forming apparatus, a method for manufacturing a film-formed product, and a method for manufacturing an electronic component.

### BACKGROUND

Wireless communication devices represented by mobile phones have a large number of semiconductor devices that are electronic components installed therein. In order to prevent an adverse effect to communication characteristics, semiconductor devices are required to suppress the adverse effect of electromagnetic waves to the interior and to the exterior, like a leakage of electromagnetic waves to the exterior. Hence, semiconductor devices having a shielding function against electromagnetic waves is utilized.

In general, semiconductor devices are formed by mounting a semiconductor chip on an interposer substrate that is a substrate for relaying to a mounting substrate, and sealing this semiconductor chip by a resin. A semiconductor device with a shielding function has been developed by providing a conductive shielding film on the upper surface of the sealing resin and the side surface thereof (see, for example, International Patent Publication No. WO 2013/035819 A1. This shielding film is referred to as an electromagnetic wave shielding film.

As for the electromagnetic wave shielding film, for example, metal materials, such as Cu, Ni, Ti, Au, Ag, Pd, Pt, Fe, Cr, SUS, Co, Zr, and Nb, are applied. In addition, the electromagnetic wave shielding film is sometimes applied as a laminated film using any one or a plurality of above metal materials. For example, an electromagnetic wave shielding film, which employs a lamination structure having a Cu film formed on an SUS film, and further having an SUS film formed thereon, is known.

Regarding electromagnetic wave shielding films, in order to obtain a sufficient shielding effect, it is necessary to decrease the electrical resistivity. Hence, the electromagnetic wave shielding film is required to have a certain thickness. Generally, in semiconductor devices, it is known that good shielding characteristics can be obtained by the film thickness of substantially 1 μm to 10 μm. In the case of above electromagnetic wave shielding films having the lamination structure of SUS, Cu and SUS, it is also known that a good shielding effect can be obtained when the film thickness is substantially 1 μm to 5 μm.

### PROBLEM TO BE SOLVED BY THE INVENTION

As for a forming method of the electromagnetic wave shielding film, a plating method is known. However, since the plating method needs a wet process, such as a pre-process, a plating processing process, and a post-process like water cleansing, an increase in the manufacturing costs of the semiconductor device is inevitable.

Hence, a sputtering method which is a dry process is now getting attention. As for a film forming apparatus by sputtering, a plasma processing apparatus for performing film formation using plasma has been proposed. Such a plasma processing apparatus introduces an inert gas into a vacuum container in which a target is placed, and applies a DC voltage. Ions of plasma inactive gas are caused to collide with the target of the film formation material, and the material beaten out from the target is deposited on the work-piece to form a film.

General plasma processing apparatuses are utilized for forming a film with a thickness of 10 nm to several 100 nm that can be formed with a process time of several 10 seconds to several minutes. As described above, however, it is necessary to form a film having a thickness in micron level as for the electromagnetic wave shielding film. Since the sputtering method is a technology of forming a film by depositing particles of a film formation material on a film forming object, the thicker the film to be formed is, the longer the time needing for forming the film becomes.

Therefore, in order to form an electromagnetic wave shielding film, a process time of several 10 minutes to an hour which is longer than typical sputtering is required. In the case of, for example, an electromagnetic wave shielding film employing a lamination structure of SUS, Cu, and SUS, a process time of 1 hour or more may be required to obtain a film thickness of 5 μm.

In this case, in the sputtering method using plasma, the semiconductor package is kept exposed to the heat of plasma during this process time. Consequently, the semiconductor package may be heated up to about 200° C. while a film having a thickness of 5 μm is obtained.

On the other hand, the heat resistant temperature of the semiconductor package is about 200° C. in the case of temporal heating of several seconds to several 10 seconds, but is generally around 150° C. when the heating exceeds several minutes. Hence, a formation of an electromagnetic wave shielding film in a micron level by general sputtering with plasma is difficult.

In order to address such difficulty, cooling units for suppressing the temperature rise of the semiconductor package may be provided in plasma processing apparatuses. However, providing the cooling units in plasma processing apparatuses makes the structure of the apparatuses complicated, resulting in increasing the size thereof, and the labor work for the maintenance of the cooling mechanism.

In order to address the foregoing technical problem, an objective of the present disclosure is to enable a film formation in micron level while suppressing a temperature rise of an electronic component without any cooling units.

### SUMMARY OF THE INVENTION

In order to achieve the above objective, a film forming apparatus according to an aspect of the present disclosure includes:

a chamber that is a container in which a sputter gas is introduced;

a carrying unit provided inside the chamber, and circulating and carrying a work-piece on a trajectory of a circular circumference; and

a plurality of film formation processing units including a sputter source depositing, on the work-piece circulated and carried by the carrying unit, a film formation material by sputtering to form a film, and a dividing member dividing a film forming position where the film is formed on the work-piece by the sputter source,

in which:

the dividing member is installed so as to divide the film forming position in a way that, in the trajectory of the circular circumference, a trajectory passing through a region other than the film forming position performing the film formation is longer than a trajectory passing through the film forming position performing the film formation.

The plurality of film formation processing units may form a film including layers formed of a plurality of film formation materials by selectively depositing the film formation materials. The plurality of film formation processing units may include the sputter sources corresponding to different kinds of film formation materials, and form a film including layers formed of plural kinds of film formation materials by selectively depositing the film formation materials kind by kind.

In the trajectory of the circular circumference, when a time for the work-piece to pass through the film forming position performing film formation by sputtering is T1, and a time for the work-piece to pass through a region where film formation is not performed is T2, the following condition may be satisfied:

0.6:10≤T1:T2<1:1.

In the trajectory of the circular circumference, a trajectory passing through the film forming position performing film formation by sputtering may correspond to a region of a partial circle with a center angle of 20 degrees to 150 degrees.

The film forming position for the film formation material forming a thickest layer may be greater than the film forming position for the film formation material forming the other layers. The film formation material for forming the thickest layer may be a material for an electromagnetic wave shielding layer.

A method for manufacturing a film-formed product according to another aspect of the present disclosure is to form a film of a film formation material, in a chamber into which a sputter gas is introduced, by circulating and carrying a work-piece by a carrying unit on a trajectory of a circular circumference, and depositing the film formation material on the work-piece by sputtering performed by a plurality of film formation processing units installed along the trajectory of the circular circumference,

in which, among the plurality of film formation processing units, while the film formation processing unit with any one kind of the film formation material is performing the film formation, the film formation processing unit with the other kind of the film formation material does not perform the film formation in a way that, in the trajectory of het circular circumference, a ratio of a region other than the film formation processing unit performing the film formation is greater than a ratio of the film formation processing unit performing the film formation.

A method for manufacturing an electronic component according to the other aspect of the present invention is to form a film of a film formation material, in a chamber into which a sputter gas is introduced by circulating and carrying the electronic component by a carrying unit on a trajectory of a circular circumference, and depositing the film formation material on the electronic component by sputtering performed by a plurality of film formation processing units installed along the trajectory of the circular circumference,

in which, among the plurality of film formation processing units, while the film formation processing unit corresponding to the film formation material for an electromagnetic wave shielding layer is performing the film formation, the film formation processing unit with the other kind of the film formation material does not perform the film formation in a way that, on the trajectory of het circular circumference, an ratio of a region other than the film formation processing unit performing the film formation is greater than an ratio of the film formation processing unit performing the film formation.

According to the present disclosure, a film forming apparatus, a method of manufacturing a film-formed product, and a method of manufacturing an electronic component are provided to enable a film formation in micron level while suppressing a temperature rise of an electronic component without any cooling units.

### BRIEF DESCRIPTION OF THE DRAWINGS

FIG. 1 is a transparent perspective view of a film forming apparatus according to an embodiment;

FIG. 2 is a schematic cross-sectional view illustrating an electronic component subjected to a film formation;

FIG. 3 is a transparent plan view of the film forming apparatus according to the embodiment;

FIG. 4 is a schematic vertical cross-sectional view along a line A-A in FIG. 3;

FIG. 5 is a block diagram illustrating a control apparatus according to the embodiment;

FIG. 6 is a plan view illustrating the size of a film formation region;

FIG. 7 is a graph illustrating a temperature change in a work-piece by a stationary sputtering apparatus;

FIG. 8 is a graph illustrating a temperature change in the work-piece according to a first example;

FIG. 9 is a graph illustrating a temperature change in the work-piece according to a second example; and

FIG. 10 is a graph illustrating a temperature change in the work-piece according to the third example.

### DETAILED DESCRIPTION OF THE EMBODIMENTS

Embodiments of the present disclosure (hereinafter, referred to as this embodiment) will be described in detail with reference to the drawings. This embodiment relates to a film forming apparatus that forms a film by sputtering.

[Overview]

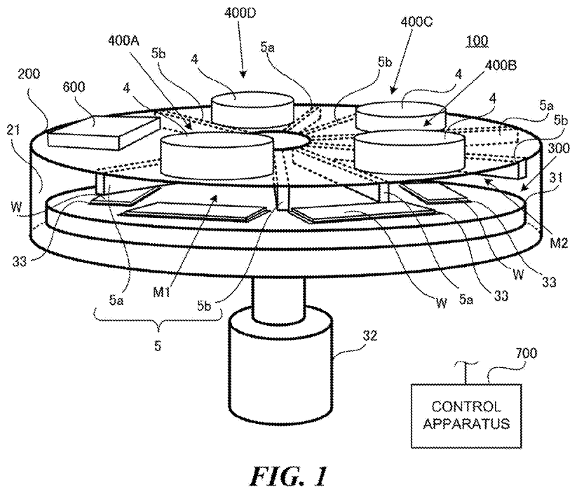

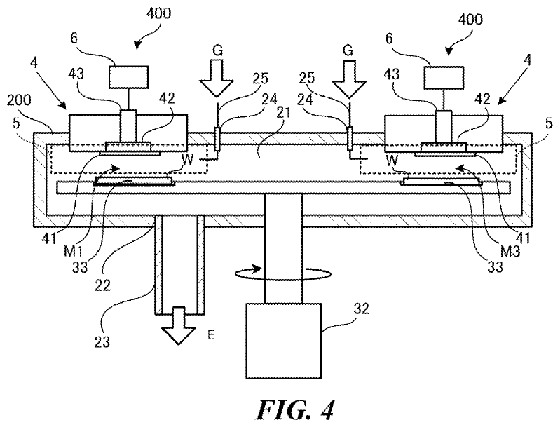

As illustrated in FIG. 1, a film forming apparatus 100 is an apparatus which, when a rotary table 31 rotates, a work-piece W held by a holder unit 33 moves on the trajectory of a circular circumference, and passes through the position facing a sputter source 4 to have particles sputtered from a target 41 deposited on to form the film (see FIG. 4).

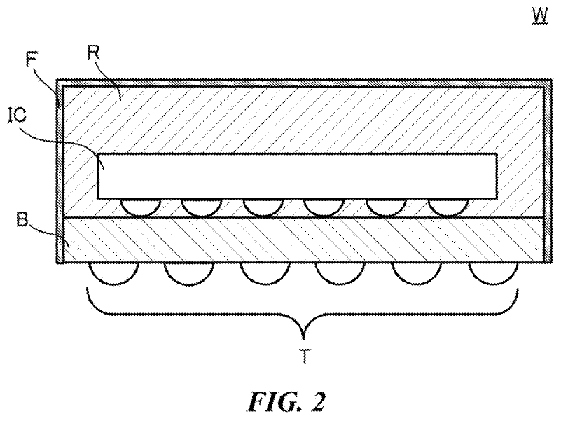

The work-piece W in this embodiment is, for example, a semiconductor package as illustrated in FIG. 2. This semiconductor package is an electronic component having a semiconductor chip IC mounted on an interposer substrate B that is a substrate relaying to a mounting substrate, and sealed by a resin R. Reference symbol T indicates an electrode for connection with the printed wiring of the mounting substrate. The film forming apparatus 100 forms a film F on the upper surface and the side surface of the resin R. This film F is a conductive electromagnetic wave shielding film. In the example illustrated in FIG. 2, the film F is also formed on the side surface of the interposer substrate B.

[Structure]

As illustrated in FIGS. 1, 3, 4, and 5, the film forming apparatus 100 includes a chamber 200, a carrying unit 300, film formation processing units 400A to 400D, a load-locking unit 600, and a control apparatus 700.

[Chamber]

As illustrated in FIG. 4, the chamber 200 is a container in which a sputter gas G is introduced. The sputter gas G is a gas for performing sputtering for causing ions, etc., produced by plasma generated by a voltage application to collide with the work-piece W. For example, an inert gas like an argon gas is applicable as the sputter gas G.

The internal space of the chamber 200 forms a vacuum chamber 21. This vacuum chamber 21 has a gas-tightness, and can be vacuumed by depressurization. For example, as illustrated in FIGS. 1 and 4, the vacuum chamber 21 is a sealed space in a cylindrical shape.

The chamber 200 has a discharge port 22 and an inlet port 24. The discharge port 22 is an opening that ensures the flow of gas between the vacuum chamber 21 and the exterior to eject a discharge gas E. This discharge port 22 is formed in, for example, the bottom of the chamber 200. A discharge part 23 is connected to the discharge port 22. The discharge part 23 includes piping, and unillustrated pumps, valves, etc. By the depressurization processing via the discharge part 23, the interior of the vacuum chamber 21 is depressurized.

In addition, the chamber 200 includes the inlet port 24. The inlet port 24 is an opening to introduce the sputter gas G near the target 41 in the vacuum chamber 21. The inlet port 24 is connected to a gas supplying unit 25. The gas supplying unit 25 is provided one by one relative to each of the targets 41. In addition, the gas supplying unit 25 includes, in addition to the piping, an unillustrated gas supplying source for the sputter gas G, pump, valve, etc. This gas supplying unit 25 introduces the sputter gas G via the inlet port 24 into the vacuum chamber 21.

[Carrying Unit]

The carrying unit 300 is provided inside the chamber 200, and circulates and carries the work-piece W on the trajectory of a circular circumference. The movement trajectory of the work-piece W by the carrying unit 300 will be referred to as a carrying path P. The term circulates and carries means moving the work-piece W around on the trajectory of a circular circumference. The carrying unit 300 includes a rotary table 31, a motor 32, and holder units 33.

The rotary table 31 is a circular plate. The motor 32 rotates the rotary table 31, which forms a circle, around the center of the circle as an axis. The holder unit 33 is a component that holds the work-piece W carried by the carrying unit 300. The work-piece W may be held by the holder unit 33 alone, or may be held by the holder unit 33 via a tray on which a plurality of work-pieces W are placed. The holder unit 33 positions the work-piece W on the rotary table 31.

The plurality of holder units 33 are installed at equal pitch. For example, each holder unit 33 is installed in a direction parallel to the tangent line of the circle in the circumferential direction of the rotary table 31, and is provided at equal pitch in the circumferential direction. More specifically, the holder unit 33 is a groove, a hole, a protrusion, a jig, a holder, etc., that holds the work-piece W or the tray. The holder unit 33 may be formed by an electrostatic chuck, a mechanical chuck, a sticking chuck, or a combination of those with a groove, a hole, a protrusion, a jig, a holder, a tray, etc. In this embodiment, since the six holder units 33 are provided, the six work-pieces W or trays are held on the rotary table 31 at the pitch of 60 degrees. However, the number of the holder units 33 may be one or more number.

[Film Formation Processing Unit]

The film formation processing units 400A to 400D are each a processing unit that performs film formation on the work-piece W carried by the carrying unit 300. Hereinafter, when the film formation processing units 400A to 400D are not distinguished, they will be collectively referred to as the film formation processing unit 400. As illustrated in FIG. 4, the film formation processing unit 400 includes a sputter source 4, a dividing member 5, and a power supply unit 6.

(Sputter Source)

The sputter source 4 is a supply source of a film formation material for depositing the film formation material on the work-piece W by sputtering to form the film. The sputter source 4 includes a target 41, a backing plate 42, and an electrode 43. The target 41 is formed of the film formation material that is to be deposited on the work-piece W to become the film, and is provided at a position facing the carrying path P spaced apart from the carrying path P. The bottom side of the target 41 faces the work-piece W moved by the carrying unit 300 and is spaced apart from the work-piece W moved by the carrying unit 300. Example film formation materials are Cu, SUS, etc. However, as long as the material is subjected to film formation by sputtering, various materials are applicable as described later. This target 41 is, for example, in a cylindrical shape. However, other shapes, such as an elongated cylindrical shape, and a rectangular cylindrical shape may be applied.

The backing plate 42 is a member that holds the target 41. The electrode 43 is a conductive member to apply power from the exterior of the chamber 200 to the target 41. The sputter source 4 is provided with a magnet, a cooling mechanism, etc., as needed.

As illustrated in FIG. 1, a plurality of the sputter sources 4 are provided on the upper lid of the chamber 200 in the circumferential direction. In the example illustrated in FIG. 1, the four sputter sources 4 are provided.

(Dividing Member)

The dividing member 5 divides film forming positions M1 to M4 where film formation is performed on the work-piece W by the sputter source 4. In the following description, when the film forming positions M1 to M4 are not distinguished, they will be collectively described as the film forming position M. As illustrated in FIG. 1, the dividing member 5 has rectangular wall plates 5a and 5b radially installed from the center of the circumference of the carrying path P, that is, from the rotation center of the rotary table 31 of the carrying unit 300. The wall plates 5a, 5b, for example, are provided on the ceiling of the vacuum chamber 21 at the positions holding the target 41 there between. The lower end of the dividing member 5 faces the rotary table via a gap which the work-piece W passes through. By providing this dividing member 5, a dispersion of the sputter gas G and the film formation material into the vacuum chamber 21 can be suppressed.

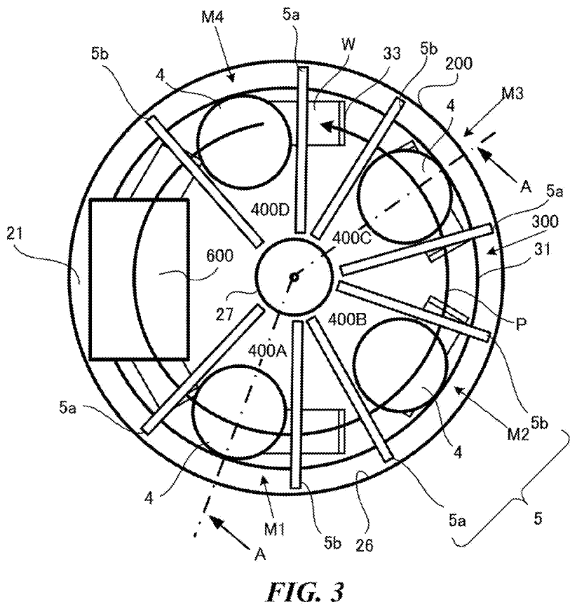

The film forming position M is a space divided by the dividing member 5 including the target 41 of the sputter source 4. More specifically, as illustrated in FIG. 3, the film forming position M is a space in a sector shape surrounded by the wall plates 5a, 5b of the dividing member 5, an inner surface 26 of the outer circumference wall of the chamber 200, and an outer surface 27 of the inner circumference wall of the chamber 200, as viewed in a planar direction. The range of the film forming position M in the horizontal direction is a region divided by the pair of wall plates 5a and 5b.

The film formation material is deposited as a film on the work-piece W passing through the position facing the target 41 at the film forming position M. Although this film forming position M is a region where the majority of the film forming process is performed, there is a leakage of the film formation material from the film forming position M even to a region other than the film forming position M, and therefore, there may be some film deposition.

In addition, the location where the temperature becomes the highest by sputtering is right below the target 41. For this reason, the temperature distribution has a deviation in the film forming position M, but each film forming position M can be considered as a collective region that contributes to the temperature rise of the work-piece W in comparison with the region other than the film forming position M.

(Power Supply Unit)

The power supply unit 6 is a component that applies power to the target 41. By applying the power to the target 41 from the power supply unit 6, the sputter gas G becomes plasma, and the film formation material is deposited on the work-piece W. In this embodiment, the power supply unit 6 is, for example, a DC power supply that applies a high voltage. In the case of an apparatus performing high-frequency sputtering, an RF power supply may be applied. The rotary table 31 has the same electrical potential as the grounded chamber 200, and by applying a high voltage to the target 41-side, a potential difference is caused. Consequently, a difficulty of connecting the rotary table 31 with the power supply unit 6 to make the movable rotary table 31 negative potential is avoided.

The plurality of the film formation processing units 400 selectively deposit the film formation material to form the film including layers formed of a plurality of film formation materials. In particular, according to this embodiment, the sputter sources 4 corresponding to the different kinds of film formation materials are provided, and by selectively depositing the film formation material kind by kind, a film including layers formed of different kinds of film formation materials is formed. The wording the sputter sources 4 corresponding to the different kinds of film formation materials are provided means a case in which the film formation materials for all film formation processing units 400 are different, and a case in which the plurality of the film formation processing units 400 have the common film formation material, but other cases are also included. The wording selectively depositing the film formation material kind by kind means that, while the film formation processing unit 400 with any one kind of the film formation material is forming the film, the other film formation processing unit 400 for the other kinds of the film formation material does not form the film. Still further, the film formation processing unit 400 during film formation or the film forming position during film formation mean the power is applied to the target 41 of the film formation processing unit 400, and the film formation processing unit 400 or the film formation position in the condition ready to perform film formation to the work piece W.

In this embodiment, the four film formation processing units 400A to 400D are installed in the carrying direction of the carrying path P. The film forming positions M1 to M4 correspond to the four film formation processing units 400A to 400D, respectively. Among those film formation processing units 400A to 400D, the film formation materials of the three film formation processing units 400A to 400C are Cu. That is, the sputter sources 4 of the film formation processing units 400A to 400C are provided with the target 41 formed of Cu. The other film formation processing unit 400 D has the film formation material that is SUS. That is, the sputter sources 4 of the film formation processing units 400D is provided with the target 41 formed of SUS. In this embodiment, while the film formation processing units 400A to 400C are performing the film forming process with Cu, the film formation processing unit 400D does not perform the film forming process with SUS. In addition, while the film formation processing unit 400D is performing the film forming process with SUS, the film formation processing units 400A to 400C do not perform the film forming process with Cu.

Moreover, in the trajectory of the circumference of the carrying path P, in order to make the trajectory passing through a region where no film formation is performed to be greater than the trajectory passing through the film forming position M where the film formation is being performed, the pitch of the dividing member 5 to divide each film forming positions M1 to M4 is set. In the embodiment, the terms “long”, “great”, etc., is used, but since the carrying path P is the trajectory in the circular circumference, the terms “long” and “great” indicate that the ratio in the finite region is large.

More specifically, when a time for the work-piece W to pass through the film forming position M of the film formation processing unit 400 during the film formation is defined as T1, and a time for passing through the region other than the film forming position M during the film formation is defined as T2, the size of the film forming position M is set to be 0.6:10≤T1:T2<1:1. When, for example, a total time for the work-piece W to pass through the film formation positions M1 to M3 while the film formation processing units 400A to 400C are performing the film forming process of a Cu film is defined as T1, and a total time for passing through the region other than the film forming positions M1 to M3 is defined as T2, 0.6:10≤T1:T2<1:1 is satisfied.

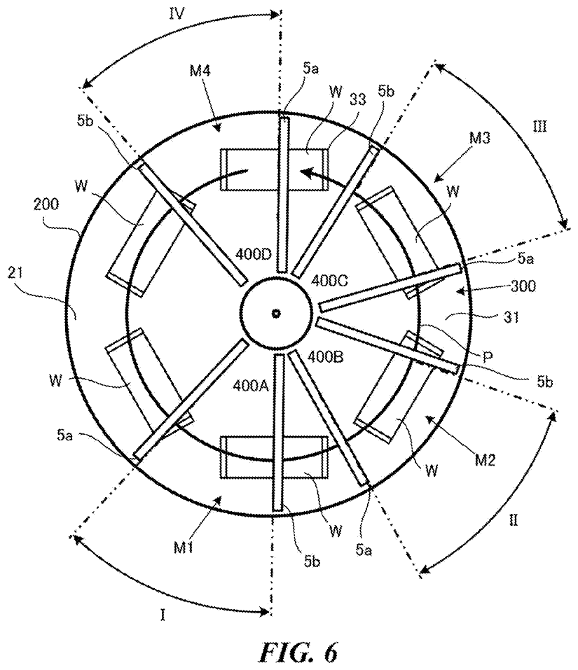

In addition, the film forming position M during the film formation corresponds to a region of a partial circle with a center angle of 20 degrees to 150 degrees. That is, the film forming position M of any one of the film formation materials corresponds to the region of the partial circle with the center angle of 20 degrees to 150 degrees. For example, as illustrated in FIG. 6, when the center angles of the carrying path P in the film forming position M1 to M3 of the film formation processing units 400A to 400C are defined as I, II, and III, respectively, the total of the center angles I, II, and III is equal to or greater than 20 degrees and equal to or less than 150 degrees. Center angles I, II, III, and IV of the carrying path P in the respective film forming positions M1 to M4 are equal to or greater than 20 degrees.

(Load-Locking Unit)

The load-locking unit 600 carries in the unprocessed work-piece W or the tray on which the work-piece W is placed from the exterior into the vacuum chamber 21 and carries out the processed work-piece W or the tray to the exterior of the vacuum chamber 21, by unillustrated carrying means, with the vacuum condition of the vacuum chamber 21 being maintained. As for this load-locking unit 600, a well-known structure is applicable, and thus the description thereof will be omitted.

[Control Apparatus]

The control apparatus 700 controls each unit of the film forming apparatus 100. This control apparatus 700 can be constructed by, for example, a special-purpose electronic circuit or a computer that runs a predetermined program. That is, as for the controls relating to the introduction and discharge of the sputter gas G and a reaction gas G2 relative to the vacuum chamber 21, the control relating to the power supply for the sputter source 4, and the control relating to the rotation of the rotary table 31, etc., are programmed as control details, and are executed by a processing device, such as a PLC or a CPU, and are adaptive to a wide variety of film formation specifications.

Example specific contents to be controlled are initial discharge pressure, selection of the sputter source 4, power application to the target 41, and flow rate, kind, introducing time, and discharging time of the sputter gas G, and a film forming time.

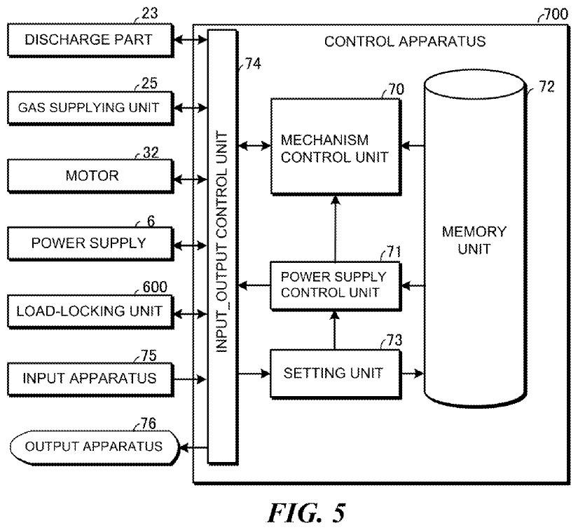

The structure of the control apparatus 700 to execute each unit as described above will be described with reference to FIG. 5 that is a virtual functional block diagram. That is, the control apparatus 700 includes a mechanism control unit 70, a power supply control unit 71, a memory unit 72, a setting unit 73, and an input and output control unit 74.

The mechanism control unit 70 is a processing unit that controls the discharge part 23, the gas supplying unit 25, the motor 32 for the carrying unit 300, drive sources for the load-locking unit 600, etc., and valves, switches, power supplies, and the like. The power supply control unit 71 is a processing unit that controls the power supply unit 6.

The control apparatus 700 selectively controls the film formation processing unit 400 in a way that, while the film formation processing unit of the any one kind of the film formation material is performing film formation, the film formation processing unit of the other kinds of the film formation materials do not perform film formation. That is, while the power supply control unit 71 applies voltage to the target 41 of the film formation processing unit 400A to 400C to perform film formation, the power supply control unit 71 does not apply voltage to the target of the film formation processing unit 400D. In addition, while the power supply control unit 71 applies voltage to the target 41 of the film formation processing unit 400D to perform film formation, the power supply control unit 71 does not apply voltage to the target 41 of the film formation processing units 400A to 400C.

The memory unit 72 is a component that stores necessary information for the control according to this embodiment. The setting unit 73 is a processing unit that sets information input from the exterior in the memory unit 72. The input and output control unit 74 is an interface that controls signal conversion and input and output between the respective components to be controlled.

In addition, the control apparatus 700 is connected with an input apparatus 75 and an output apparatus 76. The input apparatus 75 is input units, such as switches, a touch panel, a keyboard, and a mouse, for an operator to control the film forming apparatus 100 via the control apparatus 700. For example, a selection of the sputter source 4 for film formation can be input by the input units.

The output apparatus 76 is output units, such as a display, a lamp, and a meter, that enables the operator to visually check information for checking the status of the film forming apparatus 100. For example, the film forming position M corresponding to the sputter source 4 that is performing film formation can be displayed on the output apparatus 76 in a manner distinguished from the other film forming positions M.

[Action]

Actions according to this embodiment as described above will be described below with reference to FIG. 3, FIG. 4, and FIG. 6. Note that the following actions are an example case in which the film formation processing unit 400A to 400D form, on the surface of the work-piece W, an electromagnetic wave shielding film including three layers that are an adhesive layer, an electromagnetic wave shielding layer, and a protective layer. The adhesive layer formed directly on the work-piece W is an SUS layer, and is a base to enhance an intimate contact with a molding resin, and Cu. The electromagnetic wave shielding layer formed on the adhesive layer is a Cu layer, and is a layer having a function of electromagnetic wave shielding. The protective layer formed on the electromagnetic shield layer is an SUS layer, and prevents corrosion, etc., of Cu.

First, as illustrated in FIGS. 3 and 4, the carrying units of the load-locking unit 600 carries the work-piece W to be subjected to film formation sequently into the chamber 200. The rotary table 31 moves the empty holder unit 33 sequently to the carry-in position from the load-locking unit 600. The holder unit 33 holds each of the work-piece W or the tray on which the work-piece W is placed carried in by the carrying units one by one. One work-piece W may be supplied to one holder unit 33, or a plurality of the work-pieces W placed on the tray may be supplied. In this way, all work-pieces W to be subjected to film formation are placed on the rotary table 31.

The discharge part 23 discharges and depressurizes the vacuum chamber 21 to be always in the vacuum condition. The gas supplying unit 25 of the film formation processing unit 400D supplies the sputter gas G around the target 41. The rotary table 31 is rotated, and reaches a predetermined rotation speed. Accordingly, the work-piece W held by the holder unit 33 is moved along the trajectory of a circle on the carrying path P, and passes through the position facing the sputter source 4.

Next, the power supply unit 6 applies voltage only to the target 41 for the film formation processing unit 400D. Hence, the sputter gas G is changed to plasma. In the sputter source 4, ions produced by the plasma collide with the target 41, and make the particles of the film formation material fly out. Accordingly, the particles of the film formation material are deposited on the surface of the work-piece W passing through the film forming position M4 of the film formation processing unit 400D, and a film is formed. In this case, the SUS adhesive layer formed. At this time, the work-piece W passes through the film forming positions M1 to M3 of the film formation processing unit 400A to 400C, but since no power is supplied to the target 41 of the film formation processing unit 400A to 400C, the film forming process is not performed, and the work-piece W is not heated. In addition, the work-piece W is also not heated in the region other than the film forming positions M1 to M4. Therefore, in a region where no heating is performed, the work-piece W dissipates heat.

When the film forming time by film formation processing unit 400D elapses, the film formation processing unit 400D is deactivated. That is, power supply to the target 41 by the power supply unit 6 is suspended. Next, the power supply unit 6 supplies power only to the target 41 for the film formation processing unit 400A to 400C. Consequently, the sputter gas G is changed to the plasma. In the sputter source 4, ions produced by the plasma collide with the target 41, and make the particles of the film formation material fly out. Accordingly, the particles of the film formation material are deposited on the surface of the work-piece W passing through the film forming positions M1 to M3 of the film formation processing unit 400A to 400C to form a film. In this case, the Cu electromagnetic wave shielding layer is formed. Since it is necessary for the electromagnetic wave shielding layer to have a thickness thicker than those of the adhesive layer and the protective layer, the three film formation processing units 400A to 400C are simultaneously utilized. At this time, the work-piece W passes through the film forming position M4 of the film formation processing unit 400D, but since no power is supplied to the target 41 of the film formation processing unit 400D, no film formation process is performed and the work-piece W is not heated. In addition, the work-piece W is also not heated in the region other than the film forming positions M1 to M4. Therefore, in a region where no heating is performed, the work-piece W dissipates heat.

When the film forming time by the film formation processing units 400A to 400C elapses, the film formation processing units 400A to 400C are suspended. That is, power supply to the target 41 by the power supply unit 6 is suspended. Next, the power supply unit 6 supplies power only to the target 41 for the film formation processing unit 400D. Consequently, the sputter gas G is changed to the plasma. In the sputter source 4, ions produced by the plasma collide with the target 41 and make the particles of the film formation material fly out. Accordingly, the particles of the film formation material are deposited on the surface of the work-piece W passing through the film forming position M4, and the film is formed. In this case, the SUS protective layer is formed. At this time, the work-piece W passes through the film forming position M of the film formation processing units 400A to 400C, but since no power is supplied to the target 41 of the film formation processing units 400A to 400C, no film formation is performed and the work-piece W is not heated. In addition, the work-piece W is also not heated in the region other than the film forming positions M1 to M4. Therefore, in the region where no heating is performed, the work-piece W dissipates heat.

[Effects]

According to this embodiment, provided are the chamber 200 that is a container in which the sputter gas G is introduced, the carrying unit 300 installed inside the chamber 200, and circulates and carries the work-piece W on the trajectory of the circular circumference, and the film formation processing unit 400 that includes the sputter source 4 depositing the film formation material on the work-piece W circulated and carried by the carrying unit 300 by sputtering to form a film, and the dividing member 5 that divides the film forming position M where the film is formed on the work-piece W by the sputter source 4.

The dividing member 5 is installed to divide each film formation processing unit 400 in a way that, in the trajectory of the circular circumference, the trajectory passing through the region other than the film forming position M where the film is being formed is longer than the trajectory passing through the film forming position M where the film is being formed.

Hence, when passing through the space under the film formation processing unit 400 that is performing film formation, even when the temperature of the work-piece W is increased by plasma heat, the work-piece can dissipate heat while passing through the carrying path P under the film formation processing unit 400 not performing film formation or the carrying path P where no film formation processing unit 400 is present, and again return to the space under the film formation processing unit performing the film formation.

Hence, in comparison with the case in which sputtering is performed on the work-piece W at a fixed position, an excessive temperature rise of the work-piece W by plasma heat can be suppressed without any cooling units, and thus a relatively thick film in micron level can be formed. This is suitable for a formation of the electromagnetic wave shielding film in micron level on thermally sensitive semiconductor packages.

In particular, by the installation of the above dividing member 5, a time for dissipating heat by causing the work-piece W to pass through the region where no film formation is performed can be ensured longer relative to a time for the work-piece W heated by passing through the region where the film formation is performed, and thus a temperature rise of the work-piece W can be suppressed.

In addition, since it is unnecessary to provide any cooling units, the film forming apparatus 100 can employ a simplified structure, and can reduce power consumption needed for cooling. Still further, a labor work for maintenance of cooling units at constant cycle can be eliminated.

The plurality of the film formation processing units 400 have the sputter sources 4 corresponding to different kinds of the film formation materials, and by selectively depositing the film formation material kind by kind, the film including the layers formed of different kinds of film formation materials is formed. In the case of normal sputtering, when a layer formed of different kinds of film formation materials is formed, the heating of the work-piece W is likely to advance, but according to this embodiment, the temperature rise is suppressed.

When a time for the work-piece W to pass through the film forming position M of the film formation processing unit 400 performing the film formation is defined as T1, and a time for the work-piece W to pass through the region other than the film forming position M is defined as T2, the size of the film forming position M is set to satisfy 0.6:10≤T1:T2<1:1. Hence, the time for the work-piece W to dissipate heat without a film formation is ensured to be longer than the time for the work-piece W heated by the film formation, and thus the temperature rise of the work-piece W is suppressed.

In the trajectory of the circular circumference, the trajectory passing through the film forming position M where the film formation is being performed corresponds to the region of the partial circle at the center angle of 20 degrees to 150 degrees. Therefore, while ensuring the region where the film formation can be performed on the work-piece W, an increase of the region where the work-piece W is heated by the film formation is suppressed, and the region where heat is dissipated without the film formation can be ensured, and thus the optimized structure for suppressing the temperature rise of the work-piece W is employed.

The film forming position M for the film formation material forming the thickest layer is larger than the film forming position M for the film formation material forming other layers. Hence, the thick layer can be formed within a short time. In this case, the term “large” can be considered as the following cases:

(a) the trajectory for the work-piece W to pass through the film forming position M for the thickest layer is set to be longer than the trajectory for the work-piece W to pass through the film forming position M for other layers;

(b) the time for the work-piece W to pass through the film forming position M of the thickest layer is set to be longer than the time to pass through the film forming position M of other layers; and

(c) the center angle of the partial circle corresponding to the trajectory passing through the film forming position M of the thickest layer is set to be larger than the center angle of the partial circle corresponding to the trajectory passing through the film forming position M of other layers.

For example, as described above, the electromagnetic wave shielding layer is formed thicker than the underlying adhesive layer and protective film. Hence, the film forming positions M1 to M3 for the materials of the electromagnetic wave shielding layer is set to be larger than the film forming position M4 for the underlying adhesive layer and protective layer, by for example a combination of two or more film forming positions.

[Test Results]

### Comparative Example

As a comparative example, instead of a rotation carrying type, how the temperature of a work-piece rose by a film forming apparatus that performs sputtering with a work-piece held stationary on a holder will be described. The test conditions were as follows. As for the work-piece, an insulative resin substrate simulating a semiconductor package was applied.

Work-piece: insulative resin substrate.

Target: Cu (copper).

Holder: Al (aluminum).

Distance between target and work-piece: 36.0 mm.

Sputter gas: Ar, 200.9 sccm, 0.5 Pa.

DC power: 10.0 kW.

Film formation rate: 24.4 nm/s.

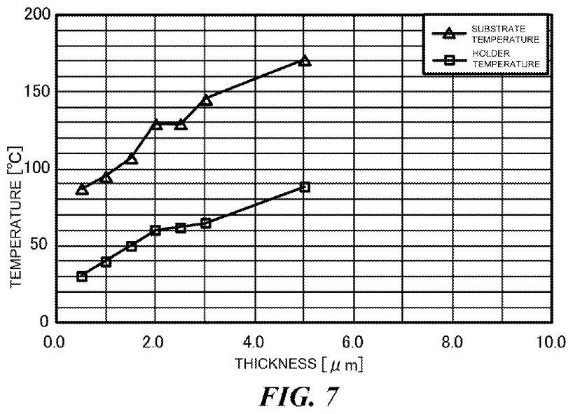

As a test results, a relationship between the film thickness, which is obtained as a result of sputtering on the substrate held by the Al holder with Cu being as target, and the temperature rise is illustrated in the graph that is FIG. 7. When sputtering was performed until the resultant thickness become 5 μm, the holder temperature became 90° C. and the substrate temperature became 170° C.

Typical semiconductor packages are likely to have a resin forming the package broken when exceeding 150° c. Hence, heating beyond 150° c. is not suitable. In this case, according to the above film forming apparatus, it is difficult to continue the film formation until the film thickness of substantially 5 μm is obtained. Therefore, a cooling mechanism is necessary.

### First Example

As a first example of the present disclosure, how the temperature of a work-piece rose when a film formation was performed by sputtering at the film forming position with the work-piece placed on the tray rotated by the rotary table will be described. The test conditions were as follows. As the work-piece, an insulative resin substrate simulating a semiconductor package was applied.

Work-piece: Insulative resin substrate.

Target: Cu.

Holder: SUS.

Distance between target and work-piece: 150 mm (face-to-face state).

Number of rotations by rotary table: 6 rpm.

Sputter gas: Ar, 100 sccm, 0.7 Pa.

DC power: 2300 W/3000 W (values of supplied power to one sputter source and of supplied power to other sputter source with film formation processing unit having two sputter sources).

Film formation rate: 0.8 nm/S.

Center angle of film forming position: 49.5 degrees.

Ratio between time T1 for passing through Cu film forming position and time T2 for passing through region where no film formation was performed: 49.5:310.5 (≅1.594:10).

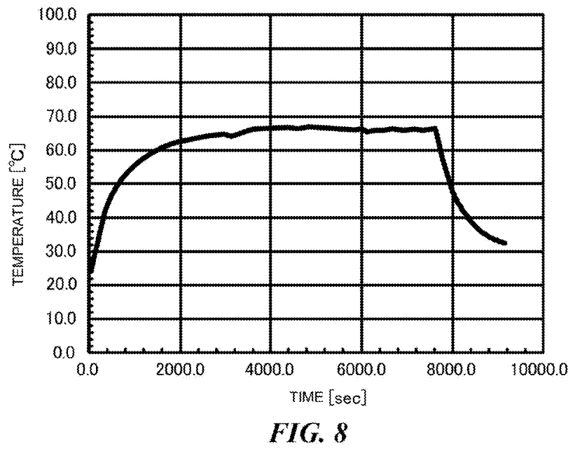

As a test result, a temperature transition when sputtering was performed for 7600 sec. on a substrate on the rotary table in the single Cu film forming position, and Cu film with a thickness of 6000 nm was obtained as illustrated in the graph that is FIG. 8.

As is clear from this graph, when sputtering was performed in the single Cu film forming position, the temperature of the substrate was 25° C. in the beginning, increased up to about 65.0° C. at 4000 sec. from the beginning, and then substantially unchanged, with no further temperature rise observed. In other words, it is clear that the temperature rise was suppressed.

In this case, when the number of film forming positions used for film formation, that is, the number of film formation processing units (n) increases, a temperature rises in multiples, for example, the temperature is expected to increase by 40° C.×n, from 25° C. that is the beginning temperature. That is, the temperature rise of, when the number of applied film formation processing units used is 2, 25° C.+40° C.×2=105° C. is expected, and when it is 3, 25° C.+40° C.×3=145° C. is expected. As described above, in view of the upper limit of the temperature rise of the semiconductor package that is 150° C., as long as the film forming position corresponds to the center angle of 49.5 degrees, like the above embodiment, even if three units are applied, the temperature does not exceed 150° C., and a good film formation result is expected.

In view of some margins, when the center angle of the single film formation position is substantially 50.0 degrees, the maximum size of the film forming positions performing the film formation is 50.0 degrees×3=150 degrees. In addition, from the standpoint of ensuring time for cooling the work-piece, the smaller the size of the film forming position is, the larger the cooling effect becomes. However, regarding the film formation efficiency, when the size is smaller than the center angle of 20 degrees, the film formation is difficult, and therefore the lower limit center angle is 20 degrees. Hence, as described above, it is desirable that the size should be set within the range of the center angle between 20 degrees to 150 degrees.

In addition, according to the above embodiment, when the total time for the work-piece W to pass through the film forming position M of the film formation processing unit 400 performing the film formation is defined as T1, and the total time passing through the region other than the film forming position M is defined as T2, the size of the film forming position M is set to satisfy 0.6:10≤T1:T2<1:1. The reason for such setting will be described with reference to the graph that is FIG. 8. FIG. 8 illustrates an example case in which a Cu film was formed to the thickness of 6000 nm (=6 μm).

First of all, the electromagnetic wave shielding film in a semiconductor package do not have to necessarily be a thickness of 6000 nm. In general, depending on the application, etc., the film thickness is set within the range of 1000 nm (1 μm) to 10000 nm (10 μm).

Hence, a case in which a Cu film with the minimum thickness of 1000 nm to be formed is considered. In this case, when a film with the thickness of 6000 nm is formed, the necessary time for film formation is ⅙ of 7600 sec., that is, 7600 sec./6=1267 sec.≅1300 sec. In addition, based on the graph that is FIG. 8, since the substrate temperature at 1300 sec. is substantially 60° C., the temperature rise of the work-piece W that is a semiconductor package is 60° C.−25° C.=35° C.

When the initial temperature of the work-piece W is 25° C. and the center angle of the film formation position is 49.5 degrees, the upper limit of the temperature rise in the case the work-piece W that is the semiconductor package is 150° C., and because (150° C.−25° C.)/35° C.≅3.6, the region that can be utilized for the film formation is the region corresponding to 3.6 positions as the film formation position with the center angle of 49.5 degrees, that is, the region corresponding to 49.5 degrees×3.6=178 degrees≅180 degrees.

In this case, during the film formation, the relationship between the film forming position M of the film formation processing unit 400 and other portions has the same ratio even when expressed by the passing time or by the center angle. Therefore, it is preferable that the upper limit of T1:T2 is less than 180:180=1:1.

In addition, a case in which a Cu film with the maximum film thickness of 10000 nm (10 μm) is formed is considered. In this case, the required time for film formation is 10/6 times as much as the time for the case of forming a film that is 6000 nm, that is, 7600 sec.×10/6=12667 sec. Since it is considered that the required time for the film formation exceeding 8 hours (28800 sec.) that is the legal working time is not preferable, this can be considered as the upper limit.

In view of the foregoing, the minimum center angle of the film forming position that can form the Cu film having the thickness of 10000 nm within 8 hours is 49.5 degrees/(28800 sec./12667 sec.)=21.8 degrees≅20 degrees. That is, since portions corresponding to 20 degrees in the trajectory of circular circumference that is 360 degrees are applicable as the regions for the film forming positions, it is preferable that the lower limit of T1:T2 is set to 20:340=0.6:10.

The graph that is FIG. 8 is for the case when a Cu film is formed. However, even when films are formed of other metals to be described later (e.g., SUS, Al, Ni, Fe, Ag, Ti, Cr, Nb, Pd, Pt, V, Ta, Au), as long as the target 41 is metal, it can be considered that power supplied to the target 41 is substantially equivalent. Hence, the heating temperature by plasma is also substantially equivalent to the Cu film, the temperature rise of the work-piece W due to film formation can also be considered to have the similar tendency. Hence, it is appropriate that, even in the case of other metals, the size of the film forming position M is set to satisfy 0.6:10≤T1:T2<1:1.

### Second Example

A second example of the present disclosure will be described. In the second example, the position M2 illustrated in FIG. 3 is not the film forming position, but is a film processing position. That is, within the common chamber 200, in addition to the film forming position, a position where the film processing is performed is provided. The film processing includes producing compound film, such as a nitride film or an oxide film, and surface processing, such as etching, cleansing, and surface roughening. The film processing is referred to as, in a sense that target 41 like in the case of sputtering is not applied, an reverse sputtering. At the film processing position, a film processing is performed while the work-piece is circulated and carried on the trajectory of a circular circumference, and when, for example, passing through the space under a cylindrical electrode where plasma is produced by applying high frequency power.

The film processing in this example is Ar bombard. The Ar bombard is also known as ion bombardment, and is to perform surface processing like cleansing or surface roughening by beating AR ionized by plasma against a surface to be processed.

In addition, in this example, an SUS film is formed using the SUS target 41 at the film forming position M3 illustrated in FIG. 3. More specifically, after the surface process by Ar bombard is performed, an SUS film formation (first time) is performed, a Cu film formation is performed, and then an SUS film formation (second time) is performed.

The film formation conditions according to the second example were as follows:

Work-piece: Insulative resin substrate.

Target: Cu (at film forming position M1),
SUS (at film forming position M3).

Holder: SUS.

Distance between target and work-piece:

Cu, 60 mm (face-to-face state),
SUS, 60 mm (face-to-face state).

Number of rotations by rotary table:

Ar bombardment, 30 rpm,
SUS, (first time) 6 rpm,
Cu, 6 rpm,
SUS, (second time) 6 rpm.

Sputter gas:

Ar, Ar bombardment, 150 sccm,
SUS (first time), 120 sccm, 0.8 Pa,
Cu, 100 sccm, 0.7 Pa,
SUS (second time), 120 sccm, 0.8 Pa.

High-frequency power supplied to cylindrical electrode to: 300 W.

DC power supplied to sputter source: 2300 W/3000 W (SUS (first time and second time), common for Cu, and in the film formation processing unit having two sputter sources, the value of power supplied to the one sputter source and the value of power supplied to the other sputter source).

Film formation rate:

SUS (first time), 0.73 nm/s,
Cu, 1.40 nm/s,
SUS (second time), 0.73 nm/s.

Center angle of each film forming position and surface processing position: 49.5 degrees.

Ratio between time T1 of passing through Cu film forming position and time T2 of passing through region where no film formation was performed: 49.5:310.5 (≅1.594:10).

Ratio between time T1 of passing through SUS film forming position and time T2 of passing through region where no film formation was performed: 49.5:310.5 (≅1.594:10).

Ratio between time T1 of passing through surface processing position and time T2 of pass through region where no surface processing was performed: 49.5:310.5 (≅1.594:10)

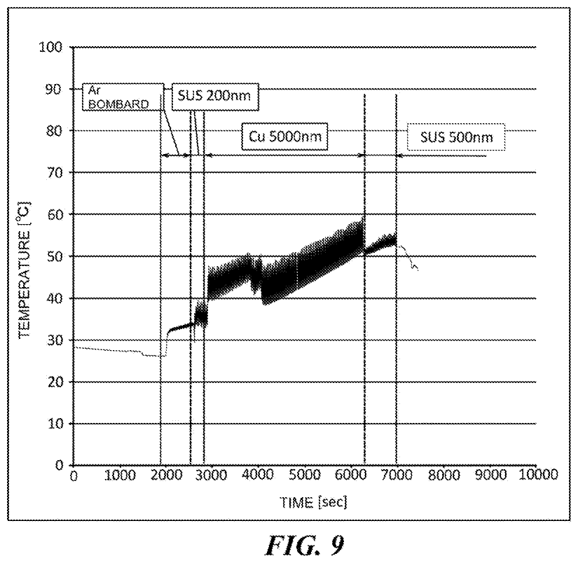

As a test result, a temperature transition of when, relative to a substrate on the rotary table, a film processing was performed for 600 sec. using the film processing position M2, a first SUS film forming process was performed for 280 sec. using the film forming position M3 to obtain a film thickness of 200 nm, a Cu film forming process was performed for 3570 sec. using the film forming position M1 to obtain a film thickness of 5000 nm, and a second SUS film forming process was performed for 690 sec. using the film forming position M3 to obtain a film thickness of 500 nm is illustrated in the graph that is FIG. 9.

As is clear from this graph, in comparison with the first example, even if sputtering was performed with an increased film formation rate at a relatively close position where the distance between the target and the work-piece was 60 mm, the temperature of the substrate was substantially 28° C. at the beginning, became substantially 40° C. in the first SUS film formation, became substantially 60° C. in the Cu film formation, and became substantially 55° C. in the second SUS film formation, but remained unchanged then. That is, when the distance between the target and the work-piece is made short, in the common sense, the temperature would further increase, but according to this example, it is observed that the temperature rise is suppressed.

Reasons why the temperature rise became equal to or lower than the temperature rise of the first example although the target was located closer and the film formation rate was increased may be because the Cu film forming time became shorter than that of first example in response to the increased film formation rate, and because the amount of heat applied after the start of film formation until the completion thereof is similar when the film thickness is similar, but thinner when the amount of heat becomes less. That is, the film thickness (5700 nm) obtained by laminating SUS and Cu according to the second example was similar to the thickness of Cu film in the first example (6000 nm), but was thinner, and thus the amount of heat was reduced.

### Third Example

A third example of the present disclosure will be described. In this example, like the second example, the position M2 illustrated in FIG. 3 is not a film forming position but a film processing position. The film processing in this example is, like the second example, Ar bombard.

In addition, in this example, like the second example, an SUS film formation using the target 41 is performed at the film forming position M3 illustrated in FIG. 3. Still further, in this example, a Cu film formation is performed at the film forming position M1 illustrated in FIG. 3, and a Cu film formation is also performed at the film forming position M4. More specifically, after the surface processing by Ar bombard, an SUS film formation (first time) is performed, and then a Cu film formation is simultaneously performed at the two film forming positions M1 and M4, and further an SUS film formation (second time) is performed. In the two film forming positions M1 and M4 where a Cu film formation is performed, the DC power to be supplied is decreased in comparison with the first and the second examples, but the total film formation rates of the two film forming positions is increased in comparison with the second example.

The film formation conditions in the third example are as follows:

Work-piece: Insulative resin substrate.

Target:

Cu (at film forming positions M1 and M4),
SUS (at film forming position M3).

Holder: SUS.

Distance between target and work-piece:

Cu (at film forming positions M1 and M4), 60 mm (face-to-face state),
SUS, 60 mm (face-to-face state).

Number of rotations of rotary table:

Ar bombardment, 30 rpm,
SUS (first time), 6 rpm,
Cu (in common at film forming positions M1 and M4), 6 rpm
SUS (second time), 6 rpm.

Sputter gas:

Ar, Ar bombard, 150 sccm,
SUS (first time), 120 sccm, 0.8 Pa,
Cu (in common at film forming positions M1 and M4), 100 sccm, 0.7 Pa,

SUS (second time), 120 sccm, 0.8 Pa.

High frequency power supplied to cylindrical electrode: 600 W.

DC power supplied to sputter source:

SUS 2300 W/3000 W (in common to first time and second time, in the film formation processing unit having two sputter sources, the value of supplied power to the one sputter source and the value of supplied power to the other sputter sources),

Cu 1800 W/2400 W (in common at film forming positions M1 and M4, in the film formation processing unit having two sputter sources, the value of supplied power to the one sputter source and the value of supplied power to the other sputter source).

Film formation rate:

SUS (first time), 0.73 nm/s,
Cu, 2.24 nm/s (1.12 nm/s at each film forming position M1, M4),
SUS (second time), 0.73 nm/s.

Center angle of Cu film forming position: 99.0 degrees (49.5 degrees at each film forming position M1, M4),

Center angle of SUS film forming position and surface processing position: 49.5 degrees.

Ratio between time T1 of passing through film forming positions M1 and M4, and time T2 of passing through region where no film formation is performed: 99:261 (≅3.793:10).

Ratio between time T1 of passing through SUS film forming position and time T2 of passing through region where no film formation is performed: 49.5:310.5 (≅1.594:10).

Ratio between time T1 of passing through surface processing position and time T2 of passing through region where no surface processing is performed: 49.5:310.5 (≅1.594:10).

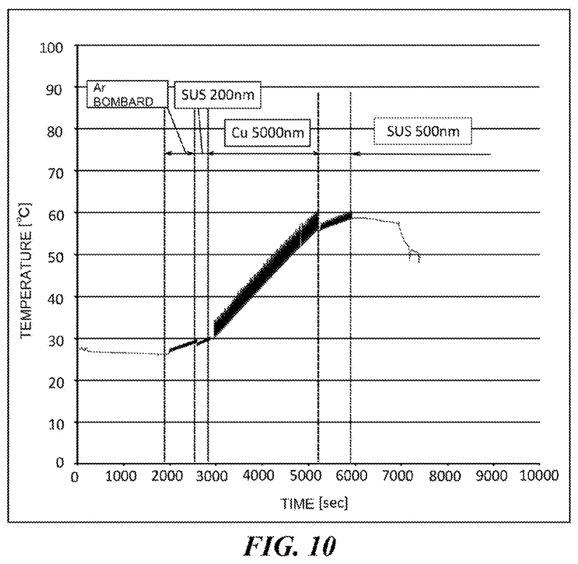

As a test result, a temperature transition of when, relative to the substrate on the rotary table, a film processing was performed for 600 sec. using the film processing position M2, a first SUS film formation was performed for 280 sec. using the film forming position M3 to obtain a thickness of 200 nm, a Cu film formation was performed for 2240 sec. using the film forming positions M1 and M4 to obtain a thickness of 5000 nm (2500 nm at each film forming position M1 and M4), and an SUS film formation was performed for 690 sec. using the film forming position M3 to obtain a thickness of 500 nm is illustrated in the graph that is FIG. 10.

As is clear from this graph, in comparison with the first example, even if sputtering was performed at a relatively close position where the distance between the target and the work-piece was 60 mm with the film formation rate being increased, the temperature of the substrate was substantially 28° C. at the beginning, became substantially 30° C. in the first SUS film formation, became substantially 60° C. in the Cu film formation, and became 60° C. in the second SUS film formation, but remained unchanged then. That is, when the distance between the target and the work-piece is made short, in the common sense, the temperature would further increase, but in this example, it is observed that the temperature rise is suppressed.

Reasons why the temperature rise became equal to or lower than the temperature rise in the first example and became similar to that of the second embodiment although the target was located closer and the film formation rate was increased may be because the Cu film forming time was shorter than that of the first example in response to the increased film formation rate, and because the amount of heat applied from the beginning of the film formation until the completion thereof is similar when the thickness is similar, but thinner when the amount of heat becomes less. That is, the thickness (5700 nm) obtained by laminating SUS and Cu in the third example is similar to the thickness (6000 nm) of Cu film in the first example, but is thinner, and thus the amount of heat was reduced.

However, since Cu film formation was simultaneously performed at the two film forming positions, the time of passing through the region where no film formation was performed is decreased in comparison with the first example and the second example. Hence, in comparison with the second example, since the temperature gradient is large, that is, the temperature rise per a unit time increases, when the film forming time is further extended, there is a possibility that a temperature rise up to substantially 100° C.

In the above second example and third example, the time T1 of passing through the film forming positions where the process time was long was set to be shorter than the time T2 of passing through the region where no film formation was performed, thereby suppressing the temperature rise of the substrate. More specifically, in the second example, the center angle of the Cu film forming position where the process time was significantly long was set to 49.5 degrees, and also in the third example, the center angle of the Cu film forming position was set to 99.0 degrees, and such setting may sufficiently suppress the temperature rise of the substrate. In addition, as for the SUS film forming position and the surface processing position, each center angle was set to 49.5 degrees, and such setting may further suppress the temperature rise.

### Other Embodiments

The present disclosure is not limited to the above embodiments, and covers the following embodiments.

(1) As for the film formation material, various materials that can form a film by sputtering are also applicable. For example, in the case of the formation of a laminated-type electromagnetic wave shielding film, the following materials are applicable.

Material for the electromagnetic wave shielding layer: Cu, Al, Ni, Fe, Ag, Ti, Cr, Nb, Pd, Pt, Co, Zr, etc.

Material of the base adhesive layer: SUS, Ni, Ti, V, Ta, etc.

Material of top protective layer: SUS, Au, etc.

In addition, the electromagnetic wave shielding layer included in the electromagnetic wave shielding film may further employ a layer structure of a plurality of materials. For example, the electromagnetic wave shielding layer may be formed by laminating a Cu layer and an Ni layer. Since Cu has a function of blocking of the electric field, while Ni has a function of blocking the magnetic field, a thinning as a whole is expected in this case. In this case, also, by selectively depositing the film formation material kind by kind, the temperature rise of the work-piece can be suppressed. Still further, each layer included in the electromagnetic wave shielding layer can be thinner than in the case of a single film formation material, the film formation time for each layer can be reduced in comparison with the case of a single film formation material, thereby suppressing the temperature rise of the work-piece.

(2) By providing a plurality of the targets in the film forming position, the film formation rate may be increased. In this case, although the temperature in each film forming position becomes high, the film forming time is reduced, resulting in achieving the similar effects to the above cases.

(3) The number of work-pieces and the number of trays to be simultaneously carried by the carrying unit, the number of the holder units for holding those may each be at least one, and not limited to the numbers described in the above embodiments as examples. That is, the single work-piece may be circulated to repeat the film formation, or equal to or greater than two work-pieces may be circulated to repeat the film formation.

(4) The work-piece and the electronic component subjected to film formation are not limited to a semiconductor package. The present disclosure is applicable to various members to which a thickness in micron level is required, and which needs a suppression of the temperature rise.

(5) Like the above second and third examples, the film processing may be performed inside a chamber having the film forming positions. However, the film processing may be performed in a different chamber from the chamber having the film forming positions.

(6) In the above embodiments, an example case in which the rotary table 31 rotates within the horizontal plane has been described. However, the direction of the rotation plane of the carrying unit is not limited to a particular direction. For example, a rotation plane that rotates within the vertical plane is also applicable. In addition, the carrying units of the carrying unit is not limited to the rotary table 31. For example, a cylindrical member having a holder unit for holding the work-piece may be applied as a rotary member that rotates around the axis. The work-piece may be held by the holder unit provided on the internal wall of the rotary member, and a plurality of film formation processing units facing outwardly relative to the work-piece may be provided on the external wall of a cylindrical, columnar, or rectangular columnar support provided inside the rotary member. Alternatively, the work-piece may be held by the holder unit provided on the external wall of the rotary member, and the plurality of film formation processing units facing inwardly relative to the work-piece may be provided on the internal wall of a cylindrical, columnar, or rectangular columnar support provided outside the rotary member. This enables a film forming process on the work-piece circulated and carried on the trajectory of a circular circumference by the rotation of the rotary member.

(7) In the above embodiments, the film is formed by selectively depositing a film formation material kind by kind. However, the present disclosure is not limited to this case, and the film formation material may be selectively deposited, as long as a film including layers formed of a plurality of film formation materials is formed. Hence, equal to or greater than two film formation materials may be deposited simultaneously. For example, an electromagnetic wave shielding film may be formed by an alloy of Co, Zr, and Nb. In this case, among the plurality of film formation processing units, the film formation processing unit with the film formation material that is Co, and the film formation processing unit with the film formation material that is Zr and the film formation processing unit with the film formation material that is Nb may be simultaneously selected to perform film formation.

In this case, the film formation processing unit applied for film formation is selected or the installation of the dividing member dividing the interior of the film formation processing unit is set in a way that, in the trajectory of the circular circumference, the trajectory passing through a region other than the film forming position performing the film formation becomes longer than the trajectory passing through the film forming position performing the film formation.

That is, in both of the cases in which one type of film formation processing unit or a plurality of types of film formation processing units are selected to perform film formation, and in which the single film formation processing unit is selected to perform film formation, the film formation processing unit applied for film formation may be selected or the installation of the dividing member dividing the interior of the film formation processing unit may be set in a way that, in the trajectory of the circular circumference, the trajectory passing through a region other than the film forming position performing the film formation becomes longer than the trajectory passing through the film forming position performing the film formation.

(8) In the above embodiments, the dividing member 5 includes the two wall plates 5a and 5b that divide the film forming position in the circumferential direction, and the space from the surface of the rotary table 31 to the ceiling of the chamber 200 is formed in between the wall plates 5a and 5b located facing each other at positions between the adjacent film forming positions. However, the present disclosure is not limited to this structure, and for example, a shield plate at the same height as the lower end of the wall plates 5a and 5b may be installed between the wall plates 5a and 5b located facing each other at positions between the adjacent film forming positions.

(9) The embodiments of the present disclosure and the modified examples of each component have been described above, but those embodiments and the modified examples are merely presented as examples, and are not intended to limit the scope of the present disclosure. Those novel embodiments can be carried out in other various forms, and various omissions, replacements, and modifications can be made thereto without departing from the scope of the present disclosure. Those embodiments and modifications thereof are also within the scope of the present disclosure, and within the scope of the invention as recited in appended claims.

What is claimed is:

1. A film forming apparatus comprising:
a chamber;
a carrying unit inside the chamber and including a rotary table having a plurality of holder units arranged along a trajectory of a circular circumference, each holder unit configured to hold one of a plurality of work-pieces, the rotary table configured to carry the plurality of work-pieces on the trajectory of the circular circumference;
a plurality of film formation processing units inside the chamber and configured to deposit a plurality of film formation materials on the plurality of work-pieces by sputtering to form films, and each film formation processing unit including:
a sputter source including a target and a power supply unit configured to apply voltage to the target for sputtering material therefrom; and
a dividing member dividing film forming positions where the films are formed on the plurality of work-pieces by the sputter source,
wherein first and second adjacent ones of the film formation processing units include a target of the same film formation material, and the dividing members are arranged to define the respective film forming positions of the first and second adjacent ones such that, in the trajectory of the circular circumference, a trajectory passing through a region other than a region defined by the first and second adjacent film forming positions is longer than a trajectory passing through a region defined by the adjacent film forming position; and
a control apparatus configured and arranged with the carrying unit and the power supply units to, while applying the voltage to the power supply units of the first and second adjacent ones of the film formation processing units and while voltage is not applied to the targets of the other film formation processing units, rotate the work-pieces through the regions of the first and second film formation processing units while sputtering the same film formation material onto the work-pieces thereat, rotate the work-pieces through the regions of the other film formation processing units without sputtering material thereon, and rotate the work pieces back through the regions of the first and second film formation processing units while sputtering more of the same film formation material thereon.
